(19) United States
(12) Patent Application Publication
(10) Pub. No.: US 2018/0076355 A1
(43) Pub. Date: Mar. 15, 2018

(54) NITRIDE SEMICONDUCTOR LIGHT EMITTING DEVICE

(71) Applicant: PANASONIC INTELLECTUAL PROPERTY MANAGEMENT CO., LTD., Osaka (JP)

(72) Inventors: Shintaro HAYASHI, Hyogo (JP); Akihiko MURAI, Osaka (JP)

(21) Appl. No.: 15/564,683

(22) PCT Filed: Mar. 22, 2016
(86) PCT No.: PCT/JP2016/001624

§ 371 Date: Oct. 5, 2017

(30) Foreign Application Priority Data
Apr. 9, 2015 (JP) 2015-080423

(51) Int. Cl. H01L 33/32; H01L 33/38; H01L 23/00; H01L 33/22; H01L 33/44; H01L 33/48; H01L 33/62; H01L 33/00

(52) U.S. Cl. CPC H01L 33/32; H01L 33/38; H01L 24/14; H01L 33/22; H01L 2933/0066; H01L 33/486; H01L 33/62; H01L 33/0095; H01L 2924/01322; H01L 33/44

(57) ABSTRACT

An n-type nitride semiconductor layer has at least an n-type AlGaN layer. The nitride semiconductor light emitting device includes a passivation film. A negative electrode includes second contact electrodes that are each in ohmic contact with the n-type AlGaN layer, and a second pad electrode that covers the second contact electrodes and is in non-ohmic contact with the n-type AlGaN layer. A metal layer, which is in non-ohmic contact with the n-type AlGaN layer, of metal layers of the second pad electrode is made from material by which reflectivity of ultraviolet radiation emitted from a luminous layer is less than 50%.

### TECHNICAL FIELD

The invention relates to nitride semiconductor light emitting devices and, more particularly, to a nitride semiconductor light emitting device configured to emit ultraviolet radiation.

### BACKGROUND ART

In a related nitride semiconductor light emitting device, there is a known ultraviolet semiconductor light emitting device that has mesa structure provided by a laminated film of an n-type layer (n-type nitride semiconductor layer) on the surface side of a substrate, a luminous layer and a p-type layer (p-type nitride semiconductor layer), and includes an n-electrode (negative electrode) provided on an exposed surface of the n-type layer and a p-electrode (positive electrode) provided on the surface side of the p-type layer (for example, Patent Literature 1).

In the ultraviolet semiconductor light emitting device described in Patent Literature 1, the n-type layer is composed of an n-type Al_{z}Ga_{1-z}N layer (0<z≦1).

An improvement in moisture resistance is desired in the nitride semiconductor light emitting device configured to emit ultraviolet radiation.

### CITATION LIST

### Patent Literature

Patent Literature 1: JP 2014-96460 A

### SUMMARY OF INVENTION

It is an object of the present invention to provide a nitride semiconductor light emitting device capable of improving moisture resistance thereof.

A nitride semiconductor light emitting device according to an aspect of the present invention includes an n-type nitride semiconductor layer that has at least an n-type AlGaN layer, a luminous layer that is formed on the n-type AlGaN layer and configured to emit ultraviolet radiation, a p-type nitride semiconductor layer that is formed on the luminous layer, a substrate that is a single crystal substrate that supports a nitride semiconductor layer including the n-type nitride semiconductor layer, the luminous layer and the p-type nitride semiconductor layer and allows the ultraviolet radiation emitted from the luminous layer to pass through, a positive electrode that is provided on a surface of the p-type nitride semiconductor layer, a negative electrode that is provided on a region, not covered with the luminous layer, of the n-type nitride semiconductor layer, an electrical insulation film in which a first contact hole which the positive electrode is disposed inside and a second contact hole which the negative electrode is disposed inside are formed, and a passivation film. The n-type nitride semiconductor layer, the luminous layer and the p-type nitride semiconductor layer are arranged from a side of the substrate in that order. The n-type AlGaN layer has a first region that the luminous layer overlaps and a second region that the luminous layer does not overlap, and is formed with a step (recess) that causes a surface of the second region to set further back than a surface of the first region toward the substrate. The electrical insulation film covers side faces and part of the surface of the p-type nitride semiconductor layer, side faces of the luminous layer, side faces of the first region of the n-type AlGaN layer and part of the surface of the second region of the n-type AlGaN layer. The positive electrode includes a first contact electrode that is disposed inside the first contact hole in the electrical insulation film and is in ohmic contact with the p-type nitride semiconductor layer, and a first pad electrode that covers the first contact electrode. The negative electrode includes second contact electrodes that are disposed inside the second contact hole in the electrical insulation film and are each in ohmic contact with the n-type AlGaN layer, and a second pad electrode that covers the second contact electrodes and is in non-ohmic contact with the n-type AlGaN layer. The passivation film covers at least surface end part of the second pad electrode and is formed with an opening that exposes central part of the second pad electrode. The second pad electrode has a laminated construction of metal layers. A metal layer as a bottom layer, which is in non-ohmic contact with the n-type AlGaN layer, of the metal layers is made from material by which reflectivity of the ultraviolet radiation emitted from the luminous layer is less than 50%.

### BRIEF DESCRIPTION OF DRAWINGS

FIG. 1 is a schematic sectional view of a nitride semiconductor light emitting device according to Embodiment 1 of the present invention;

FIG. 2 is a schematic plan of the nitride semiconductor light emitting device;

FIG. 3 exemplifies a current-voltage characteristic graph of the nitride semiconductor light emitting device;

FIGS. 4A to 4D are schematic diagrams illustrating an estimation mechanism of electrically insulating an n-type AlGaN layer in a comparison example;

FIGS. 5A and 5B are schematic diagrams illustrating an estimation mechanism by which the occurrence of a malfunction in the nitride semiconductor light emitting device according to Embodiment 1 of the present invention is suppressed;

FIG. 6 is a schematic plan of a nitride semiconductor light emitting device according to Modified Example 1 of Embodiment 1 of the present invention;

FIG. 7 is a schematic plan of a nitride semiconductor light emitting device according to Modified Example 2 of Embodiment 1 of the present invention;

FIG. 8 is a schematic sectional view of a nitride semiconductor light emitting device according to Modified Example 3 of Embodiment 1 of the present invention;

FIG. 9 is a schematic sectional view of a nitride semiconductor light emitting device according to Modified Example 4 of Embodiment 1 of the present invention;

FIG. 10 is a schematic sectional view of a nitride semiconductor light emitting device according to Embodiment 2 of the present invention;

FIG. 11 is a schematic diagram illustrating an estimation mechanism of the nitride semiconductor light emitting device;

FIG. 12 is a schematic sectional view of a nitride semiconductor light emitting device according to Embodiment 3 of the present invention; and

FIG. 13 is a schematic diagram illustrating an estimation mechanism of the nitride semiconductor light emitting device.

### DESCRIPTION OF EMBODIMENTS

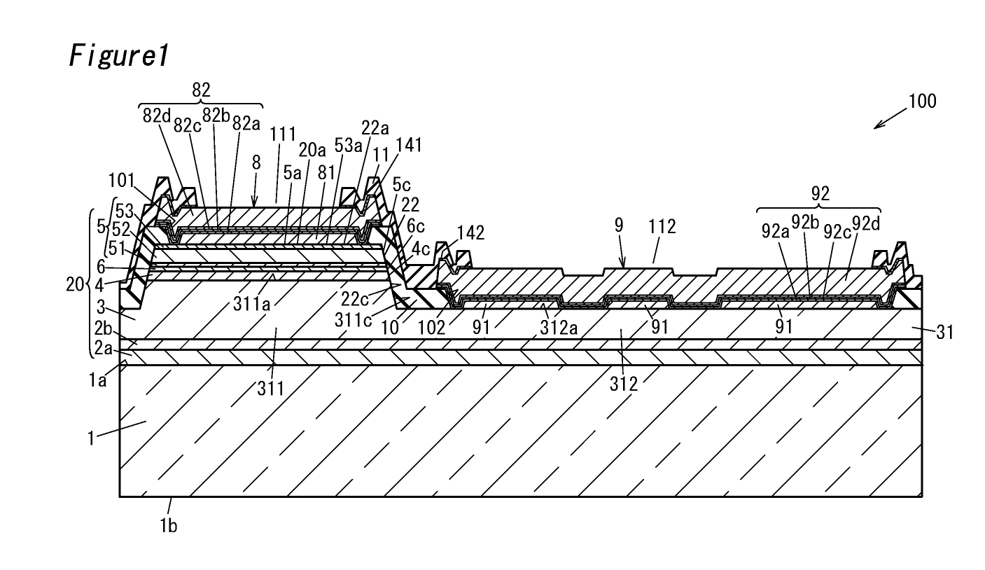

Each figure to be explained in the following Embodiments 1 to 3 and the like is a schematic diagram, and ratios about respective thickness and dimensions among components in FIGS. 1, 4, 5 and 8 to 13 do not necessarily represent actual dimensional ratios.

### Embodiment 1

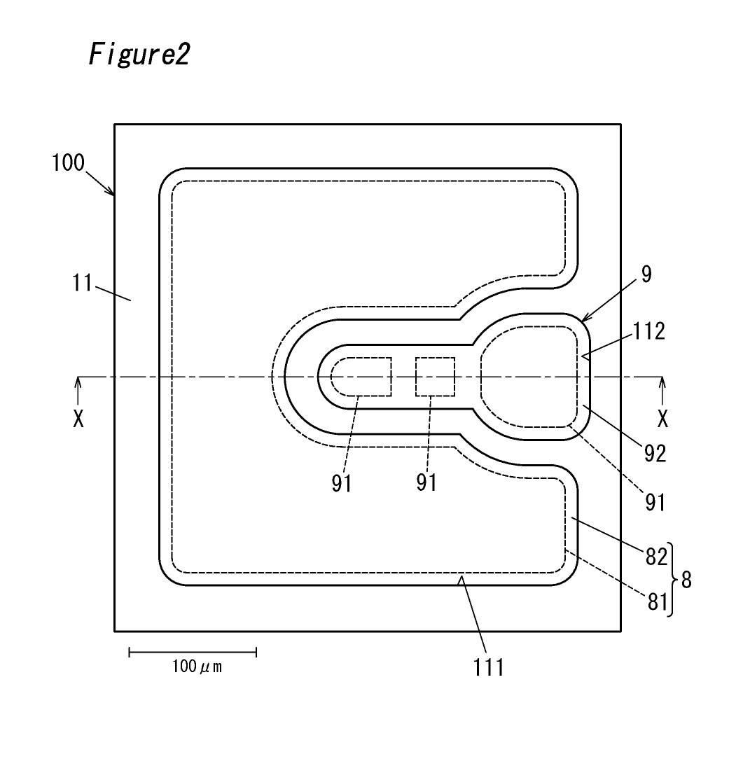

Hereinafter, a nitride semiconductor light emitting device 100 according to the present embodiment (hereinafter, also abbreviated to “light emitting device 100”) will be explained with reference to FIGS. 1 to 3. FIG. 1 is a schematic sectional view taken along an X-X line in FIG. 2.

The light emitting device 100 includes a substrate 1, an n-type nitride semiconductor layer 3, a luminous layer 4 configured to emit ultraviolet radiation, a p-type nitride semiconductor layer 5, an electrical insulation film 10, a positive electrode 8, a negative electrode 9 and a passivation film 11. The substrate 1 is a single crystal substrate that has a first surface 1a and a second surface 1b and allows the ultraviolet radiation emitted from the luminous layer 4 to pass through. The n-type nitride semiconductor layer 3 is formed on the first surface 1a of the substrate 1 and has at least an n-type AlGaN layer 31. The n-type AlGaN layer 31 has a first region 311 that the luminous layer 4 overlaps and a second region 312 that the luminous layer 4 does not overlap, and is formed with a step (recess) that causes a surface 312a of the second region 312 to set further back than a surface 311a of the first region 311 toward the first surface 1a of the substrate 1. The luminous layer 4 is formed on the first region 311 of the n-type AlGaN layer 31. The p-type nitride semiconductor layer 5 is formed on the luminous layer 4. The electrical insulation film 10 covers side faces 5c and part of the surface 5a of the p-type nitride semiconductor layer 5, side faces 4c of the luminous layer 4, side faces 311c of the first region 311 of the n-type AlGaN layer 31 and part of the surface 312a of the second region 312 of the n-type AlGaN layer 31. The electrical insulation film 10 is formed with a first contact hole 101 which the positive electrode 8 is disposed inside and a second contact hole 102 which the negative electrode 9 is disposed inside. The positive electrode 8 includes a first contact electrode 81 that is disposed inside the first contact hole 101 in the electrical insulation film 10 and is in ohmic contact with the p-type nitride semiconductor layer 5, and a first pad electrode 82 that covers the first contact electrode 81. The negative electrode 9 includes (e.g., three) second contact electrodes 91 that are disposed inside the second contact hole 102 in the electrical insulation film 10 and are each in ohmic contact with the n-type AlGaN layer 31. The negative electrode 9 also includes a second pad electrode 92 that covers the second contact electrodes 91 and is in non-ohmic contact with the n-type AlGaN layer 31. The passivation film 11 covers at least surface end part of the second pad electrode 92 and is formed with an opening 112 that exposes central part of the second pad electrode 92. The second pad electrode 92 has a laminated construction of (e.g., four) metal layers 92a, 92b, 92c and 92d. The metal layer 92a, which is in non-ohmic contact with the n-type AlGaN layer 31, of the metal layers 92a, 92b, 92c and 92d is made from material by which reflectivity of the ultraviolet radiation emitted from the luminous layer 4 is less than 50%. The light emitting device 100 having the configuration as explained above can improve moisture resistance thereof. In the light emitting device 100, the second surface 1b of the substrate 1 functions as a light extraction surface.

The light emitting device 100 is a ultraviolet LED chip (Light Emitting Diode Chip) configured to emit ultraviolet radiation. In an example, a chip size of the light emitting device 100 is set to be 400 μm □(400 μm×400 μm).

Components of the light emitting device 100 will be hereinafter explained in detail.

The light emitting device 100 is a ultraviolet LED chip configured to emit ultraviolet radiation having a peak emission wavelength in a ultraviolet wavelength band of, for example 210 nm to 360 nm. In this case, the light emitting device 100 can be utilized for application fields such as high efficiency white illumination, sterilization, medical care and high-speed processing of environmental contaminant. The “peak emission wavelength” is a peak emission wavelength at a room temperature (27° C.).

In the application field of sterilization, the light emitting device 100 preferably has a peak emission wavelength in a wavelength band of, for example 260 nm to 285 nm. In this case, the light emitting device 100 can emit ultraviolet radiation having a 260 nm to 285 nm band that is easily absorbed by respective DNA of virus and bacteria, thereby efficiently performing sterilization. It is also preferable that the light emitting device 100 have a peak emission wavelength in a UV-C wavelength band. According to the classification of ultraviolet wavelength by, for example the International Commission on Illumination (CIE), the UV-C wavelength band is a 100 nm to 280 nm band.

The single crystal substrate forming the substrate 1 is preferably a sapphire substrate. In the first surface 1a of the substrate 1, an off-angle from (0001) plane is preferably 0° to 0.5°, more preferably 0.05° to 0.4°, or further more preferably 0.1° to 0.31°.

The n-type nitride semiconductor layer 3 formed on the first surface 1a of the substrate 1 is preferably formed on the substrate 1 through a first buffer layer 2a and a second buffer layer 2b. That is, the light emitting device 100 preferably includes the first and second buffer layers 2a and 2b between the substrate 1 and the n-type nitride semiconductor layer 3. In the case of the light emitting device 100, the first buffer layer 2a is formed directly on the first surface 1a of the substrate 1, and the n-type nitride semiconductor layer 3 is formed directly on the second buffer layer 2b that is on the first buffer layer 2a.

In the present description, examples of being “formed on the first surface 1a of the substrate 1” include being formed directly on the first surface 1a of the substrate 1, being formed on the first surface 1a of the substrate 1 through the first and second buffer layers 2a and 2b, and being formed on the first surface 1a of the substrate 1 only through the first buffer layer 2a.

The first buffer layer 2a is composed of AlₓGa₁₋ₓN (0<x≦1) layer. The first buffer layer 2a is preferably composed of an AlN layer.

An object of the first buffer layer 2a is to improve respective crystallinity of the n-type nitride semiconductor layer 3, the luminous layer 4 and the p-type nitride semiconductor layer 5. The light emitting device 100 includes the first buffer layer 2a, thereby enabling the reduction in dislocation density and improvement on the respective crystallinity of the n-type nitride semiconductor layer 3, the luminous layer 4 and the p-type nitride semiconductor layer 5. The light emitting device 100 can accordingly improve the luminous efficiency. In the light emitting device 100, the first buffer layer 2a being made too thin causes insufficient reduction in threading dislocation. The dislocation density of the first buffer layer 2a is preferably 5×10⁹ cm⁻³ or less. In addition, the first buffer layer 2a of the light emitting device 100 being made too thick may cause the occurrence of crack by lattice mismatch with the substrate 1, peeling of the first buffer layer 2a from the substrate 1, and too large warping of a wafer forming light emitting devices 100. For example, the thickness of the first buffer layer 2a is preferably about 500 nm to 10 μm, and more preferably 1 μm to 5 μm. In an example, the first buffer layer 2a is 4 μm in thickness.

The second buffer layer 2b intervenes between the first buffer layer 2a and the n-type nitride semiconductor layer 3. The second buffer layer 2b is provided in order to reduce the threading dislocation of the luminous layer 4 and residual strain of the luminous layer 4. The second buffer layer 2b is composed of Al_{y}Ga_{1-y}N (0<y≦1), where a composition ratio of Al is greater than that of the n-type nitride semiconductor layer 3, and a lattice constant difference with respect to the first buffer layer 2a is less than that of the n-type nitride semiconductor layer 3. A composition ratio of Al_{y}Ga_{1-y}N layer (0<y<1, y<x) forming the second buffer layer 2b is preferably set so that the luminous layer 4 can efficiently emit ultraviolet radiation. The second buffer layer 2b is, for example an Al_{0.95}Ga_{0.05}N layer. For example, the second buffer layer 2b is 0.03 μm to 1 μm in thickness. In an example, the second buffer layer 2b is 0.5 μm in thickness.

In the light emitting device 100, the n-type nitride semiconductor layer 3 is a layer for transporting electrons to the luminous layer 4. The n-type nitride semiconductor layer 3 may be composed of, for example the n-type AlGaN layer 31. The n-type AlGaN layer 31 is an n-type Al_{z}Ga_{1-z}N layer (0<z<1). The n-type Al_{z}Ga_{1-z}N layer (0<z<1) is preferably set so that a composition ratio of Al (z) allows the luminous layer 4 to efficiently emit ultraviolet radiation. For example, the composition ratio of Al (z) may be 0.55 that is the same as a composition ratio of Al in a barrier layer, when the luminous layer 4 has quantum well structure that is composed of the barrier layer and a well layer, the well layer is composed of an Al_{0.45}Ga_{0.55}N layer, and the barrier layer is composed of an Al_{0.55}Ga_{0.45}N layer. That is, the n-type AlGaN layer 31 may be the Al_{0.55}Ga_{0.45}N layer. The composition ratio of Al (z) in the n-type Al_{z}Ga_{1-z}N layer (0<z<1) is not limited to the same as the composition ratio of Al in the barrier layer, but may be different therefrom. In an example, the n-type nitride semiconductor layer 3 is 2 μm in thickness. For example, the n-type nitride semiconductor layer 3 preferably contains donor impurity such as Si. In addition, the n-type nitride semiconductor layer 3 is preferably about 1×10¹⁸ to 1×10¹⁹ cm⁻³ in electron concentration.

The n-type nitride semiconductor layer 3 needs to include at least the n-type AlGaN layer 31, but may include, in addition to the n-type AlGaN layer 31, an n-type AlGaN layer that is different in a composition ratio of Al from the n-type AlGaN layer 31. In the light emitting device 100, the n-type AlGaN layer 31 doubles as an n-type contact layer. In other words, the n-type AlGaN layer 31 has a function as the n-type contact layer.

The luminous layer 4 is between the n-type nitride semiconductor layer 3 and the p-type nitride semiconductor layer 5. The luminous layer 4 is a layer for converting carriers injected (here, electrons and holes) into light. In other words, the luminous layer 4 is a layer for emitting ultraviolet radiation as a result of recombination between electrons injected from the n-type nitride semiconductor layer 3 and holes injected from the p-type nitride semiconductor layer 5. The luminous layer 4 preferably has the quantum well structure. In the luminous layer 4, preferably, the well layer of the quantum well structure is composed of an AlₐGa₁₋ₐN layer (0<a<1), and the barrier layer of the quantum well structure is composed of an Al_{b}Ga_{1-b}N layer (0<b≦1, b>a). The emission wavelength of the light emitting device 100 can be set to an arbitrary emission wavelength in a range of 210 nm to 360 nm by varying the composition ratio of Al (a) in the AlₐGa₁₋ₐN layer (0<a<1). For example, the composition ratio of Al (a) need be set to 0.45 when a desired emission wavelength of the light emitting device 100 is around 275 nm. The well layer of the quantum well structure in the luminous layer 4 may be composed of an InAlGaN layer.

The quantum well structure may be multi-quantum well structure or single quantum well structure. It is considered that if the well layer of the luminous layer 4 in the light emitting device 100 is made too thick, luminous efficiency thereof decreases because electrons and holes injected into the well layer are separated spatially by a piezoelectric field caused by lattice mismatch in the quantum well structure, thereby reducing recombination efficiency. The “electrons and holes . . . are separated spatially” means that the electrons and holes are separated so that they exist at both ends of the well layer (at both the side of the p-type nitride semiconductor layer 5 and the side of the n-type nitride semiconductor layer 3). It is also considered that if the well layer of the luminous layer 4 is made too thin, luminous efficiency thereof decreases because a carrier confinement effect decreases. Therefore, for example, a thickness of the well layer is preferably about 1 nm to 5 nm, or more preferably about 1.3 nm to 3 nm. For example, the barrier layer is also preferably about 5 nm to 15 nm in thickness. In an example of the light emitting device 100, the well layer is 2 nm in thickness, and the barrier layer is 10 nm in thickness. The light emitting device 100 is not limited to the configuration in which the luminous layer 4 has the quantum well structure, but may have double heterostructure in which the luminous layer 4 is sandwiched between the n-type nitride semiconductor layer 3 and the p-type nitride semiconductor layer 5.

The light emitting device 100 preferably has a cap layer 6 between the luminous layer 4 and the p-type nitride semiconductor layer 5. The cap layer 6 is a diffusion prevention layer for suppressing the diffusion of impurities in the p-type nitride semiconductor layer 5 toward the luminous layer 4. Examples of the impurities in the p-type nitride semiconductor layer 5 include acceptor impurity of the p-type nitride semiconductor layer 5. The cap layer 6 is an Al_{w}Ga_{1-w}N layer (0<w<1). In an example, a composition ratio of Al (w) in the Al_{w}Ga_{1-w}N layer (0<w<1) is 0.55. The composition ratio of Al (w) in the Al_{w}Ga_{1-w}N layer (0<w<1) is, but not limited to, 0.55, and needs to be greater than a composition ratio of Al in the well layer and less than a composition ratio of Al in an electron blocking layer 51 to be described later. The cap layer 6 is, for example 5 nm in thickness.

The p-type nitride semiconductor layer 5 includes at least a p-type AlGaN layer 52. For example, the p-type nitride semiconductor layer 5 preferably includes the electron blocking layer 51 and a p-type contact layer 53 in addition to the p-type AlGaN layer 52.

The electron blocking layer 51 is preferably provided between the luminous layer 4 and the p-type AlGaN layer 52. The electron blocking layer 51 is a layer that prevents electrons, not recombined with holes in the luminous layer 4, of electrons injected from the n-type nitride semiconductor layer 3 to the luminous layer 4 from leaking (overflowing) into the side of the p-type AlGaN layer 52. The electron blocking layer 51 may be composed of a p-type Al_{c}Ga_{1-c}N layer (0<c<1). A composition ratio of Al (c) in the p-type Al_{c}Ga_{1-c}N layer (0<c<1) is, for example 0.9. The composition ratio of the p-type Al_{c}Ga_{1-c}N layer (0<c<1) is preferably set so that band-gap energy of the electron blocking layer 51 is higher than band-gap energy of the p-type AlGaN layer 52 or the barrier layer. In an example, the electron blocking layer 51 is 30 nm in thickness. In the light emitting device 100, the electron blocking layer 51 being made too thin may decrease suppression performance of electron overflow, while the electron blocking layer 51 being made too thick may cause an increase in resistance of the emitting device 100. A thickness of the electron blocking layer 51 is not decided definitely because an appropriate thickness thereof varies according to a value such as the composition ratio of Al (c) or concentration of holes, but is preferably 1 nm to 50 nm and more preferably 5 nm to 25 nm. For example, the acceptor impurity of the electron blocking layer 51 is preferably Mg.

The p-type AlGaN layer 52 is a layer for transporting holes to the luminous layer 4. The p-type AlGaN layer 52 is preferably composed of a p-type Al_{d}Ga_{1-d}N layer (0<d<1). A composition ratio of the p-type Al_{d}Ga_{1-d}N layer (0<d<1) is preferably set so as to suppress ultraviolet radiation emitted from the luminous layer 4 being absorbed into the p-type Al_{d}Ga_{1-d}N layer (0<d<1). For example, when the composition ratio of Al in the well layer of the luminous layer 4 is 0.5 and the composition ratio of Al in the barrier layer is 0.7, a composition ratio of Al (d) in the p-type Al_{d}Ga_{1-d}N layer (0<d<1) may be 0.55 that is the same as the composition ratio of Al (b) in the barrier layer. That is, when the well layer of the luminous layer 4 is composed of an Al_{0.45}Ga_{0.55}N layer, the p-type AlGaN layer 52 may be composed of, for example a p-type Al_{0.55}Ga_{0.45}N layer. The composition ratio of Al in the p-type AlGaN layer 52 is not limited to the same as the composition of Al (b) in the barrier layer, but may be different therefrom. For example, the acceptor impurity of the p-type AlGaN layer 52 is preferably Mg.

The p-type AlGaN layer 52 preferably has a higher concentration of holes in a hole concentration range by which a film quality of the p-type AlGaN layer 52 is not degraded. However, the p-type AlGaN layer 52 being made too thick causes the resistance of the light emitting device 100 to become too large because the concentration of holes in the p-type AlGaN layer 52 is lower than the concentration of electrons in the n-type nitride semiconductor layer 3. Therefore, a thickness of the p-type AlGaN layer 52 is preferably 200 nm or less and more preferably 100 nm or less. In an example, the p-type AlGaN layer 52 of the light emitting device 100 is 50 nm in thickness.

The p-type nitride semiconductor layer 5 may preferably include the p-type contact layer 53 on the p-type AlGaN layer 52.

The p-type contact layer 53 is provided in order to acquire excellent ohmic contact with the first contact electrode 81 of the positive electrode 8 by decreasing contact resistance with the first contact electrode 81. For example, the p-type contact layer 53 is preferably composed of a p-type GaN layer. The p-type GaN layer forming the p-type contact layer 53 preferably has concentration of holes that is higher than that in the p-type AlGaN layer 52. The p-type contact layer 53 comprised of the p-type GaN layer can have excellent ohmic contact with the first contact electrode 81 by the concentration of holes that is set to about 7×10¹⁷ cm⁻³. Note that the concentration of holes in the p-type GaN layer may be changed in a hole concentration range by which excellent ohmic contact with the first contact electrode 81 is acquired. For example, the p-type contact layer 53 is preferably 50 nm to 300 nm in thickness. In an example, the p-type contact layer 53 is 200 nm in thickness.

As can been seen from the above, the light emitting device 100 includes the substrate 1 that supports a nitride semiconductor layer 20 as a laminated body that includes the n-type nitride semiconductor layer 3, the luminous layer 4 and the p-type nitride semiconductor layer 5. The substrate 1 is the single crystal substrate. The substrate 1 allows the ultraviolet radiation emitted from the luminous layer 4 to pass through. The nitride semiconductor layer 20 may include, for example, the first buffer layer 2a, the second buffer layer 2b, the n-type nitride semiconductor layer 3, the luminous layer 4, the cap layer 6 and the p-type nitride semiconductor layer 5. The nitride semiconductor layer 20 may be appropriately provided with the first buffer layer 2a, the second buffer layer 2b, the luminous layer 4, the cap layer 6, the electron blocking layer 51 and the p-type contact layer 53. The nitride semiconductor layer 20 is provided on the first surface 1a as one surface of the substrate 1. The n-type nitride semiconductor layer 3, the luminous layer 4 and the p-type nitride semiconductor layer 5 are arranged from the first surface 1a of the substrate 1 in that order. The nitride semiconductor layer 20 may be formed by an epitaxial growth method. Examples of the epitaxial growth method include an MOVPE (metal organic vapor phase epitaxy) method, an HYPE (hydride vapor phase epitaxy) method, an MBE (molecular beam epitaxy) method and the like. The nitride semiconductor layer 20 may contain impurities such as H, C, O, Si and Fe, inescapably mixed when the nitride semiconductor layer 20 is formed.

The nitride semiconductor layer 20 has a mesa structure 22. The mesa structure 22 is formed by etching part of the nitride semiconductor layer 20 from the side of a surface 20a of the nitride semiconductor layer 20 up to intermediate part of the n-type nitride semiconductor layer 3. Thus, the n-type AlGaN layer 31 is formed with the step so that the light emitting device 100 exposes the surface 312a of the second region 312 in the n-type AlGaN layer 31.

The electrical insulation film 10 is preferably formed over part of an upper surface 22a of the mesa structure 22 (surface 20a of nitride semiconductor layer 20), side faces 22c of the mesa structure 22, and part of the surface 312a of the second region 312 in the n-type AlGaN layer 31. Accordingly, the electrical insulation film 10 also covers side faces 6c of the cap layer 6 in the mesa structure 22 of the light emitting device 100. The electrical insulation film 10 is a film that is electrically non-conductive. Material of the electrical insulation film 10 is preferably SiO₂. In short, the electrical insulation film 10 is preferably a silicon oxide film. The material of the electrical insulation film 10 is not limited to SiO₂, but examples thereof may further include Si₃N₄, Al₂O₃, TiO₂, Ta₂O₅, ZrO₂, Y₂O₃, CeO₂, Nb₂O₅ and the like. In an example, the electrical insulation film 10 is 800 nm in thickness.

The electrical insulation film 10 is formed with the first contact hole 101 that exposes the first contact electrode 81 of the positive electrode 8, and one second contact hole 102 that exposes the (e.g., three) second contact electrodes 91 of the negative electrode 9.

The first contact hole 101 preferably has an opening area that gradually increases in a direction apart from the p-type nitride semiconductor layer 5 in a thickness direction of the p-type nitride semiconductor layer 5. Specifically, it is preferable that the first contact hole 101 of the electrical insulation film 10 have a tapered inner peripheral surface, and thereby the opening area of the first contact hole 101 gradually increases in the direction apart from the p-type nitride semiconductor layer 5 in the thickness direction of the p-type nitride semiconductor layer 5. The first contact hole 101 is greater than the first contact electrode 81 of the positive electrode 8 in planar view. The inner peripheral surface of the first contact hole 101 is apart from side faces of the first contact electrode 81.

The second contact hole 102 preferably has an opening area that gradually increases in a direction apart from the surface 312a of the second region 312 of the n-type AlGaN layer 31 in a thickness direction of the n-type AlGaN layer 31. Specifically, it is preferable that the second contact hole 102 of the electrical insulation film 10 have a tapered inner peripheral surface, and thereby the opening area of the second contact hole 102 gradually increases in the direction apart from the surface 312a of the second region 312 of the n-type AlGaN layer 31 in the thickness direction of the n-type AlGaN layer 31. The second contact hole 102 is greater than a group of the second contact electrodes 91 of the negative electrode 9 in planar view. The inner peripheral surface of the second contact hole 102 is apart from respective side faces of the second contact electrodes 91.

The first contact electrode 81 of the positive electrode 8 is a contact electrode that is formed on the surface 5a of the p-type nitride semiconductor layer 5 in order to acquire ohmic contact with the p-type nitride semiconductor layer 5. In an example, the first contact electrode 81 is formed by forming a laminated film of a Ni film and an Au film (hereinafter also referred to as a “first laminated film”) on the surface 5a of the p-type nitride semiconductor layer 5 and then performing an annealing process. In an example of the first laminated film, the Ni film is 30 nm in thickness, and the Au film is 200 nm in thickness.

The first contact electrode 81 preferably has a cross section that gradually decreases in the direction apart from the p-type nitride semiconductor layer 5 in the thickness direction of the thickness direction 5. Specifically, the first contact electrode 81 has the side faces that are tapered, and thereby the cross section gradually decreases in the direction apart from the p-type nitride semiconductor layer 5 in the thickness direction of the thickness direction 5.

The first pad electrode 82 of the positive electrode 8 is an electrode for connection with an outside. In other words, the first pad electrode 82 is a mounting electrode. Specifically, when the light emitting device 100 is packaged or mounted on a wiring board or the like, a conductive wire, a conductive bump or the like is joined to the first pad electrode 82. Examples of the conductive wire include an Au wire and the like. Examples of the conductive bump include an Au bump and the like.

The first pad electrode 82 is formed over the first contact electrode 81 and the electrical insulation film 10 in planar view. In short, the first pad electrode 82 is formed to encompass the first contact hole 101, and a peripheral edge of the first contact hole 101 on a surface of the electrical insulation film 10 in planar view. In other words, the first contact hole 101, and the peripheral edge of the first contact hole 101 on the surface of the electrical insulation film 10 in the light emitting device 100 are in a vertical projection area of the first pad electrode 82 with a projection direction thereof being along the thickness direction of the p-type nitride semiconductor layer 5. The first pad electrode 82 preferably has tapered side faces.

The first pad electrode 82 has structure in which metal layers 82a, 82b, 82c and 82d are stacked. Hereinafter, the metal layers 82a, 82b, 82c and 82d are referred to as a first metal layer 82a, a second metal layer 82b, a third metal layer 82c and a fourth metal layer 82d in order apart from the p-type nitride semiconductor layer 5.

The first metal layer 82a, the second metal layer 82b, the third metal layer 82c and the fourth metal layer 82d in the first pad electrode 82 are composed of a Ti layer, an Al layer, a Ti layer and an Au layer, respectively. For example, the first metal layer 82a, the second metal layer 82b, the third metal layer 82c and the fourth metal layer 82d are 100 nm, 250 nm, 100 nm and 1300 nm in thickness, respectively. Material of the first metal layer 82a is preferably one kind selected from the group consisting of Ti, Mo, Cr and W.

The second contact electrodes 91 of the negative electrode 9 are formed on the surface 312a of the second region 312 in the n-type AlGaN layer 31 with the second contact electrodes 91 arranged apart from each other inside the one second contact hole 102. From a different point of view, the second contact electrodes 91 are separated into division zones on the surface 312a of the second region 312 in the n-type AlGaN layer 31.

Each of the second contact electrodes 91 preferably has a cross section that gradually decreases in a direction apart from the surface 312a of the second region 312 in the thickness direction of the n-type AlGaN layer 31. Specifically, each of the second contact electrodes 91 preferably has the cross section that gradually decreases in the direction apart from the surface 312a of the second region 312 in the thickness direction of the n-type AlGaN layer 31. Each of the second contact electrodes 91 preferably includes tapered side faces.

Each of the second contact electrodes 91 is a contact electrode formed on the surface 312a of the second region 312 in the n-type AlGaN layer 31 in order to acquire ohmic contact with the n-type AlGaN layer 31. In an example, each of the second contact electrodes 91 is formed by forming a laminated film of an Al film, an Ni film, an Al film, an Ni film and an Au film (hereinafter referred to as a “second laminated film”) on the surface 312a of the second region 312 in the n-type AlGaN layer 31 and then performing an annealing process. The Al film, the Ni film, the Al film, the Ni film and the Au film of the second laminated film are, for example, 200 nm, 30 nm, 200 nm, 30 nm and 200 nm in thickness, respectively.

Each of the second contact electrodes 91 has solidification structure that contains main components such as Ni and Al. The light emitting device 100 can accordingly reduce contact resistance between the n-type AlGaN layer 31 and the second contact electrodes 91. The “solidification structure” means crystal structure produced as a result of transformation from melting metal into solid. In other words, the solidification structure is melt solidification structure formed as a result of solidification of melting metal containing Ni and Al. The solidification structure containing main components such as Ni and Al may contain, for example impurities such as Au and N.

The light emitting device 100 has the reduced contact resistance between the n-type AlGaN layer 31 and the second contact electrodes 91, thereby enabling reduction in operating voltage of the light emitting device 100 and improvement in luminance.

Each of the second contact electrodes 91 is not limited to the structure containing main components such as Ni and Al, but may be composed of another material containing components such as Ti and the like.

In the light emitting device 100, each contact between the n-type AlGaN layer 31 and the second contact electrodes 91 of the negative electrode 9 is ohmic contact. Here, the “ohmic contact” means contact, without rectification of current that occurs according to a direction of voltage applied, of contact between the n-type AlGaN layer 31 and the second contact electrodes 91. The ohmic contact has current-voltage characteristics that are preferably almost linear or more preferably linear. The ohmic contact also preferably has smaller contact resistance. With the contact between the n-type AlGaN layer 31 and the second contact electrodes 91, current passing through interfaces between the n-type AlGaN layer 31 and the second contact electrodes 91 is considered to be a sum of thermionic emission current over schottky barrier and tunnel current passing through the schottky barrier. It is therefore considered that when mainly the tunnel current passes therethrough, the contact between the n-type AlGaN layer 31 and the second contact electrodes 91 is approximately ohmic contact.

The second pad electrode 92 of the negative electrode 9 is an electrode for connection with an outside. In other words, the second pad electrode 92 is a mounting electrode. Specifically, when the light emitting device 100 is packaged or mounted on a wiring board or the like, a conductive wire, a conductive bump or the like is joined to the second pad electrode 92.

The second pad electrode 92 is formed over the second contact electrodes 91 and the electrical insulation film 10 in planar view. In short, the second pad electrode 92 is formed to encompass the second contact hole 102, and a peripheral edge of the second contact hole 102 on the surface of the electrical insulation film 10 in planar view. In other words, the second contact hole 102, and the peripheral edge of the second contact hole 102 on the surface of the electrical insulation film 10 are in a vertical projection area of the second pad electrode 92 with a projection direction thereof being along the thickness direction of the n-type AlGaN layer 31. The second pad electrode 92 preferably includes tapered side faces.

The second pad electrode 92 has structure in which the metal layers 92a, 92b, 92c and 92d are stacked. Hereinafter, the metal layers 92a, 92b, 92c and 92d are referred to as a first metal layer 92a, a second metal layer 92b, a third metal layer 92c and a fourth metal layer 92d in order apart from the surface 312a of the second region 312 in the n-type AlGaN layer 31.

The first metal layer 92a, the second metal layer 92b, the third metal layer 92c and the fourth metal layer 92d in the second pad electrode 92 are composed of a Ti layer, an Al layer, a Ti layer and an Au layer, respectively. The first metal layer 92a, the second metal layer 92b, the third metal layer 92c and the fourth metal layer 92d are 100 nm, 250 nm, 100 nm and 1300 nm in thickness, respectively. Material of the second pad electrode 92 as a bottom layer is one kind selected from the group consisting of Ti, Mo, Cr and W. The light emitting device 100 accordingly enables improvement in adhesion of the second contact electrodes 91 and the electrical insulation film 10 with respect to the metal layer 92a as the bottom layer.

Material of the metal layer 92a as the bottom layer is preferably one kind selected from the group consisting of Ti, Mo, Cr and W. The second pad electrode 92 can accordingly have non-ohmic contact as contact with the n-type AlGaN layer 31 with reflectivity of the ultraviolet radiation emitted from the luminous layer 4 being less than 50%.

The “non-ohmic contact” is contact that is not regarded as ohmic contact, and is typically schottky contact. The “schottky contact” means contact with rectification of current that occurs according to a direction of voltage applied.

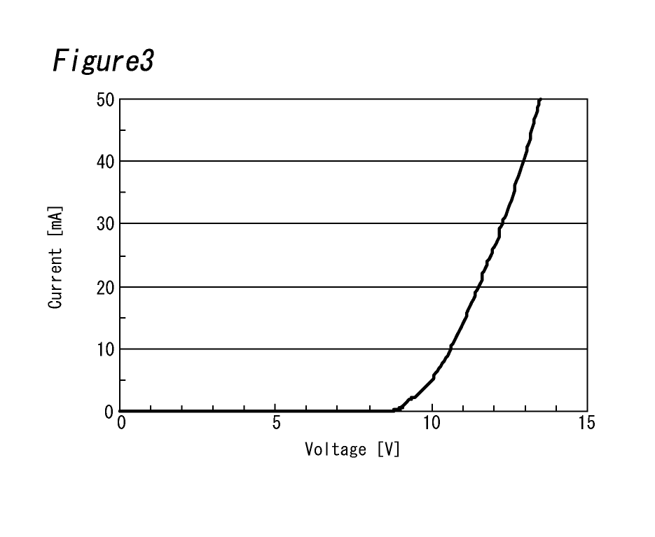

In the present description, a lower limit of contact resistance of the contact between the second pad electrode 92 and the n-type AlGaN layer 31, regarded as the non-ohmic contact may be determined by forward direction voltage (Vf) in current-voltage characteristics of the light emitting device 100. FIG. 3 illustrates a measurement result showing an example of the current-voltage characteristics of the light emitting device 100. Although theoretical forward direction voltage of the light emitting device 100 estimated from bandgap is about 4.7 V, the forward direction voltage of the light emitting device 100 in the example was about 9 V as shown in FIG. 3. The light emitting device 100 preferably has a small difference between the actual forward direction voltage and the theoretical forward direction voltage because voltage corresponding to the difference between the actual forward direction voltage and the theoretical forward direction voltage causes a power loss. The contact resistance between the second region 312 of the n-type AlGaN layer 31 and second contact electrodes needs to be made less than 1×10⁻² Ω·cm² in order that the difference between the actual forward direction voltage and the theoretical forward direction voltage is made, for example less than 6 V. From these viewpoints, the lower limit of the contact between the second pad electrode 92 and the n-type AlGaN layer 31 regarded as the non-ohmic contact may be, for example 1×10⁻² Ω·cm².

The reflectivity provided by the “material by which reflectivity of the ultraviolet radiation emitted from the luminous layer 4 is less than 50%” is a measurement value with an integrating sphere and a spectrophotometer. Measurement results were obtained from reflectivity evaluation samples. Each of the reflectivity evaluation samples was made by depositing a metal layer on a silicon substrate. Different kinds of reflectivity evaluation samples were prepared as the reflectivity evaluation samples. In the different kinds of reflectivity evaluation samples, Ti, Mo, Cr, W and another different metal were employed as material of each metal layer. Reflectivity that is less than 50% with respect to ultraviolet radiation having a wavelength of 210 nm to 360 nm was acquired in cases where material of each metal layer in the reflectivity evaluation samples was one kind selected from the group consisting of Ti, Mo, Cr and W. Each respective reflectivity in the reflectivity evaluation samples was less than 50% regardless of polarization, incident angle and the like. In order to measure reflectivity of ultraviolet radiation on each metal layer, ultraviolet radiation reflected with the ultraviolet radiation onto each metal layer of the reflectivity evaluation samples having an incident angle of 3° was converged with the integrating sphere and then measured with the spectrophotometer.

Preferably, the first pad electrode 82 of the positive electrode 8 and the second pad electrode 92 of the negative electrode 9 in the light emitting device 100 are formed from the same material and provided with the same laminated structure. The first pad electrode 82 and the second pad electrode 92 can accordingly be formed at the same time when the light emitting device 100 is produced.

Note that a plan-view size of at least one second contact electrode 91 of the second contact electrodes 91 in the light emitting device 100 are preferably greater than a circle having a diameter of 45 μm. In other words, at least one second contact electrode 91 of the second contact electrodes 91 in the light emitting device 100 is preferably greater than the circle having the diameter of 45 μm as seen from a thickness direction of the substrate 1. The light emitting device 100 can accordingly have the second pad electrode 92, a surface shape of which is a shape having a flat region that is greater in plan-view size than the circle having the diameter of 45 μm. It is therefore possible to stably form an Au bump made of a general wire bonder on the second pad electrode 92. The Au bump made of the general wire bonder is 45 μm to 100 μm in diameter.

The light emitting device 100 can also have the negative electrode 9 that is prevented from peeling off from the n-type AlGaN layer 31 because adhesion between the second contact electrodes 91 and the second region 312 of the n-type AlGaN layer 31 in the negative electrode 9 is higher than adhesion between the second pad electrode 92 and the second region 312 of the n-type AlGaN layer 31 and thereby the second contact electrodes 91 exists in almost the whole of a vertical projection area of the flat region of the second pad electrode 92.

In an example, the passivation film 11 is formed to cover end part of the first pad electrode 82 of the positive electrode 8, end part of the second pad electrode 92 of the negative electrode 9, and the electrical insulation film 10. Specifically, the passivation film 11 is formed to cover a surface and the side faces of the first pad electrode 82, a surface and the side faces of the second pad electrode 92, and the electrical insulation film 10, and also formed with an opening 111 that exposes central part of the first pad electrode 82 (central part of surface of first pad electrode 82) (opening 111 is hereinafter referred to as a “first opening 111”), and the opening 112 that exposes the central part of the second pad electrode 92 (central part of surface of second pad electrode 92) (opening 112 is hereinafter referred to as a “second opening 112”). The passivation film 11 needs to be formed on at least the second pad electrode 92 and formed with the opening 112 that exposes the central part of the second pad electrode 92. The passivation film 11 is a protective film that becomes an outermost layer in the light emitting device 100. The passivation film 11 is a protective film that suppresses characteristic degradation caused by humidity and the like of outside air. Specifically, the passivation film 11 is a protective film that protects at least respective functions of the second pad electrode 92 of the negative electrode 9, the second contact electrodes 91 and the n-type AlGaN layer 31, thereby suppressing the characteristic degradation of the light emitting device 100. Examples of the characteristics of the light emitting device 100 include optical characteristic, electrical characteristic and the like. Examples of the optical characteristic of the light emitting device 100 include optical output, emission wavelength, lumen maintenance factor and the like. Examples of the electrical characteristic of the light emitting device 100 include ESD (electrostatic discharge) resistance, drive voltage, reverse bias leakage current and the like. The optical output of the light emitting device 100 can be measured with the integrating sphere and a spectrometer.

The first opening 111 preferably has an opening area that gradually increases in a direction apart from the p-type nitride semiconductor layer 5 in the thickness direction of the p-type nitride semiconductor layer 5. The first opening 111 in the passivation film 11 preferably has a tapered inner peripheral surface.

The second opening 112 preferably has a tapered inner peripheral surface, thereby having an opening area that gradually increases in a direction apart from the surface 312a of the second region 312 in the n-type AlGaN layer 31 in the thickness direction of the n-type AlGaN layer 31. The second opening 112 in the passivation film 11 preferably has the tapered inner peripheral surface.

For example, the passivation film 11 is preferably a silicon nitride film. The passivation film 11 can accordingly have moisture permeability that is smaller than that of a silicon oxide film, and a high moisture resistance. The passivation film 11 is electrically non-conductive. The passivation film 11 is preferably formed by a plasma CVD method. The light emitting device 100 can accordingly have step coverage by the passivation film 11 and dense degree of the passivation film 11 that are improved as compared with cases where the passivation film 11 is formed by an evaporation method or a sputtering method. The passivation film 11 is, for example 700 nm in thickness.

The light emitting device 100 preferably includes a first adhesion layer 141 that intervenes between the passivation film 11 and surface end part of the first pad electrode 82 in the positive electrode 8. The light emitting device 100 also preferably includes a second adhesion layer 142 that intervenes between the passivation film 11 and surface end part of the second pad electrode 92 in the negative electrode 9.

Each of the first and second adhesion layers 141 and 142 is a layer that has high adhesion to the passivation film 11 as compared with the first and second pad electrodes 82 and 92. Each material of the first and second adhesion layers 141 and 142 is preferably one kind selected from the group consisting of Ti, Cr, Nb, Zr, TiN and TaN.

Each of the first and second adhesion layers 141 and 142 is, for example 20 nm in thickness.

Hereinafter, a light emitting device (100) production method will be explained.

(1) Preparing Wafer

The wafer is a substrate that is circular in shape. When the substrate 1 of the light emitting device 100 is a sapphire substrate, a sapphire wafer can be employed as the wafer. The sapphire wafer has a first surface that corresponds to the first surface 1a of the substrate 1. The first surface of the sapphire wafer preferably has an off-angle from (0001) plane of 0° to 0.5°.

(2) Process for Stacking Nitride Semiconductor Layer 20 on First Surface of Wafer

The process includes forming the nitride semiconductor layer 20 by the epitaxial growth method.

In the process, the MOVPE method is employed as the epitaxial growth method for the nitride semiconductor layer 20. In the process, a low pressure MOVPE method is preferably employed as the MOVPE method.

Trimethylaluminum (TMAl) is preferably employed as a source gas of Al. Trimethylgallium (TMGa) is preferably employed as a source gas of Ga. NH₃ is preferably employed as a source gas of N. Tetraethylsilane (TESi) is preferably employed as a source gas of Si that is impurity for providing n-type conductivity. Bis(cyclopentadienyl)magnesium (Cp₂Mg) is preferably employed as a source gas of Mg that is impurity contributing to p-type conductivity. For example, H₂ gas is preferably employed as a carrier gas for each of the source gases.

Substrate temperature, V/III ratio, feed rate of each source gas, growth pressure and the like need to be set appropriately as a growth condition of the nitride semiconductor layer 20. The V/III ratio is a ratio of a mol rate of the source gas of N that is group V element [μmol/min] to a total mol rate of source gases of group III element (source gas of Al and source gas of Ga) [μmol/min]. The “growth pressure” is a pressure in a reactor of MOVPE apparatus with the source gases and respective carrier gases supplied to the reactor.

The epitaxial growth method of the nitride semiconductor layer 20 is not limited to the MOVPE, but may be, for example, an MBE method, an HVPE method or the like.

(3) Process for Annealing in Order to Activate p-Type Impurities

The process is a process for activating the p-type impurities of the p-type nitride semiconductor layer 5 by annealing for a prescribed annealing time at a prescribed annealing temperature in an annealing furnace of annealing apparatus. Specifically, the process includes activating respective p-type impurities of the electron blocking layer 51, the p-type AlGaN layer 52 and the p-type contact layer in the p-type nitride semiconductor layer 5. The annealing condition includes an annealing temperature of 600 to 800° C., and an annealing time of 10 to 50 minutes. Examples of the annealing apparatus include a lamp annealing apparatus, electric annealing furnace, and the like.

(4) Process for Forming Mesa Structure 22

The process includes forming a first resist layer on a region corresponding to the upper surface 22a of the mesa structure 22 in the surface 20a of the nitride semiconductor layer 20 by photolithography technique. The process also includes forming the mesa structure 22 by etching part of the nitride semiconductor layer 20 from the side of the surface 20a up to the intermediate part of the n-type nitride semiconductor layer 3, and then removing the first resist layer. For example, the etching of the nitride semiconductor layer 20 is preferably performed through dry etching apparatus. For example, the dry etching apparatus is preferably an inductively coupled plasma etching system.

(5) Process for Forming Electrical Insulation Film 10

The process includes forming a silicon oxide film as a base of the electrical insulation film 10 on the whole of the first surface side of the wafer by, for example a PECVD (plasma-enhanced Chemical Vapor Deposition) method. The process also includes forming the electrical insulation film 10 by patterning the silicon oxide film so that the first and second contact holes 101 and 102 are pierced in the silicon oxide film. The patterning of the silicon oxide film is performed by, for example, photolithography technique and etching technology.

(6) Process for Forming Second Contact Electrodes 91 of Negative Electrode 9

The process includes a first step for forming a second resist layer that is obtained by patterning so that only a region to be formed with the negative electrode 9 (i.e., part of surface 312a of second region 312 in n-type AlGaN layer 31) is exposed in the side of the first surface of the wafer. The process also includes a second step for forming a laminated film on the surface 312a of the second region 312 in the n-type AlGaN layer 31 by the evaporation method, where the laminated film contains an Al film, an Ni film, an Al film, an Ni film and an Au film that are stacked in order apart from the surface 312a. The process also includes a third step for removing the second resist layer and undesired films on the second resist layer by lift-off. The process further includes a fourth step for forming the second contact electrodes 91 by performing an annealing process and then performing slow cooling. The annealing process is preferably RTA (Rapid Thermal Annealing) in N₂ gas atmosphere. In the process, the annealing process is preferably performed with infrared annealing apparatus.

For example, a condition for the RTA process includes the annealing temperature of 650° C. and the annealing time of one minute. The annealing temperature is preferably a temperature that is a eutectic point of AlNi (640° C.) or more, and less than 700° C. The annealing temperature may be appropriately changed based on a composition ratio of Al in the n-type AlGaN layer 31. For example, the annealing time is preferably set to be in a range of about 30 seconds to three minutes. The “eutectic point” means a solidification temperature when liquid eutectic mixture produces a mixture in solid phase that has the same composition.

The “performing slow cooling” means gradually cooling. A cooling rate (hereinafter referred to as a “slow cooling rate”) when the slow cooling is performed may be, for example 30° C./min. The cooling rate is not limited to 30° C./min. Preferably, the cooling rate is appropriately set to be in a range of, e.g., 20 to 60° C./min.

(7) Process for Forming First Contact Electrode 81 of Positive Electrode 8

The process includes forming the first contact electrode 81 on the surface 5a of the p-type nitride semiconductor layer 5.

Specifically, the process includes forming a third resist layer that is obtained by patterning so that only a region to be formed with the positive electrode 8 on the side of the first surface of the wafer (part of surface 53a of p-type contact layer 53) is exposed. The process also includes forming a laminated layer of, for example, an Ni film that is 30 nm in thickness and an Au film that is 200 nm in thickness by an electron-beam evaporation method, and then removing the third resist layer and undesired films on the third resist layer by performing lift-off. The process further includes performing the RTA process in N₂ gas atmosphere so that the contact between the first contact electrode 81 and the p-type nitride semiconductor layer 5 is made ohmic contact. A condition of the RTA process may include, for example, the annealing temperature of 500° C. and the annealing time of 15 minutes.

(8) Process for Forming First Pad Electrode 82 of Positive Electrode 8 and Second Pad Electrode 92 of Negative Electrode 9

The process includes forming a fourth resist layer by patterning so that only respective regions to be formed with the first pad electrode 82 and the second pad electrode 92 on the side of the first surface of the wafer are exposed. The process also includes forming the first pad electrode 82 and the second pad electrode 92 by forming a laminated film of, for example, a Ti layer that is 100 nm in thickness, an Al layer that is 250 nm in thickness, a Ti layer that is 100 nm in thickness and an Au layer that is 1300 nm in thickness by the electron-beam evaporation method. The process further includes removing the fourth resist layer and undesired films on the fourth resist layer by performing lift-off.

(9) Process for Forming Passivation Film 11

The process includes forming a silicon nitride film as a base of the passivation film 11 on the whole of the first surface side of the wafer by the plasma CVD method. The process also includes forming the passivation film 11 by patterning the silicon nitride film so that the first opening 111 and the second opening 112 are pierced in the silicon nitride film on the first surface side of the wafer. The patterning of the silicon nitride film is performed by, for example, photolithography technique and etching technology.

(10) Process for Forming Break Grooves

The process includes forming break grooves that reach intermediate part of the wafer in the thickness direction of the wafer from the surface side of the passivation film 11. In the process, the break grooves are preferably formed by ablation processing with a laser beam machine. The ablation processing means laser beam machining under an irradiation condition by which ablation occurs.

(11) Process for Polishing Wafer

The process includes thinning the thickness of the wafer so that the thickness corresponds to a prescribed thickness of the substrate 1, by polishing the wafer from the side of a second surface on the opposite side of the first surface. Preferable polishing of the wafer is sequentially performing a grinding process and a lapping process.

With the light emitting device (100) production method, the processing has been performed, and thereby the wafer formed with light emitting devices 100 is produced. That is, in the light emitting device (100) the production method, the processes (1) to (11) have been performed sequentially, and thereby the wafer formed with light emitting devices 100 is produced.

(12) Process for Dividing the Wafer Formed with Light Emitting Devices 100 into Individual Light Emitting Devices 100 (Dividing Process)

The dividing process is a process for dividing the wafer formed with light emitting devices 100 into individual light emitting devices 100. The dividing process includes dividing the wafer along the break grooves after the lapping process. Specifically, the dividing process includes a breaking process and an expanding process. After the expanding process, the individual light emitting devices 100 may be picked up by an appropriate pickup tool and then stored in, for example a chip tray or the like.

The breaking process includes, for example dividing the wafer into individual light emitting devices 100 with a blade. In the breaking process, the wafer is sandwiched from both sides in the thickness direction by two wafer tapes. The wafer tapes are resin adhesive tapes. After the wafer is divided into the individual light emitting devices 100, the wafer tape of the two wafer tape on the nitride semiconductor layers 20 of the wafer is removed.

In the expanding process, the wafer tape on the second surfaces 1b of the substrates 1 in the light emitting devices 100 is expanded by, for example expanding apparatus, and thereby each interval between adjoining light emitting devices 100 is expanded.

With the light emitting device (100) production method, by performing the dividing process, each part of the first surface of the sapphire wafer after the lapping process corresponds to the first surface 1a of the substrate 1, and each part of the second surface of the sapphire wafer corresponds to the second surface 1b of the substrate 1.

The dividing process may include cutting the wafer formed with light emitting devices 100 by a dicing saw or the like, thereby dividing the wafer into individual light emitting devices 100.

As stated above, the light emitting device (100) production method enables facilitation of production of the light emitting devices 100 capable of improving their respective moisture resistance.

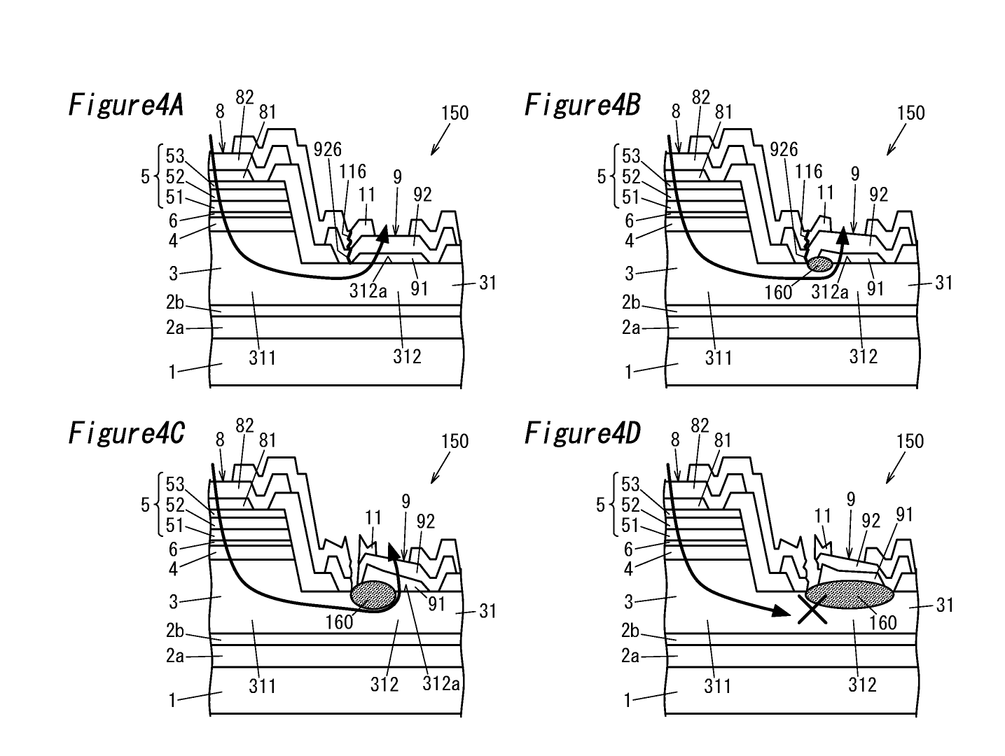

At the research stage for developing the light emitting device 100 capable of improving the moisture resistance, the present inventors fabricated nitride semiconductor light emitting devices 150 as a comparison example (see FIG. 4A) and evaluated their respective moisture resistance. The nitride semiconductor light emitting device 150 (hereinafter referred to as a “light emitting device 150”) has a configuration similar to that of the light emitting device 100, and differs from the light emitting device 100 in that a first pad electrode 82 of a positive electrode 8 is comprised of only material that is the same as the fourth metal layer 82d of the light emitting device 100 and a second pad electrode 92 of a negative electrode 9 is comprised of only material that is the same as the fourth metal layer 92d of the light emitting device 100. The light emitting device 150 also differs therefrom in that it does not include components corresponding to the first and second adhesion layers 141 and 142 of the light emitting device 100. The light emitting device 150 also differs from the light emitting device 100 in that the negative electrode 9 has only one second contact electrode 91 and a plan-view size of the second contact electrode 91 equal the plan-view size that encompass the second contact electrodes 91 of the light emitting device 100.

In order to evaluate the moisture resistance of each light emitting device 150 as the comparison example, the present inventors perform an energizing test under high humidity and high temperature, and perform evaluation of electrical characteristic, appearance inspection by an optical microscope and a SEM (scanning electron microscope), and the like. In the energizing test under high humidity and high temperature, temperature, relative humidity, electric current and continuous energization time were 60° C., 80RH %, 20 mA and 2000 hours, respectively. The present inventions came to realize that the light emitting device 150 as the comparison example needed further improving moisture resistance thereof. Specifically, the present inventors obtain knowledge that malfunction may occur in the light emitting device 150 as the comparison example during the energizing test under high humidity and high temperature. The “malfunction” was open failure, damage to end part of second pad electrode 92, damage to part of passivation film 11 on the damage end part of second pad electrode 92, and the like. The “malfunction” is caused by corrosion of a region just under negative electrode 9 on second region 312 of n-type AlGaN layer 31. The “corrosion of a region just under negative electrode 9 on second region 312 of n-type AlGaN layer 31” means oxidation of the region just under second contact electrode 91 of second region 312 of n-type AlGaN layer 31, and Al₂O₃ being formed. With the light emitting device 150 as the comparison example, the present inventors also confirmed that even when the malfunction occurred, no corrosion occurred in p-type contact layer 53 comprised of p-type GaN layer, and no damage occurred to end part of first pad electrode 82 of positive electrode 8.

An estimation mechanism about the malfunction occurrence in the light emitting device 150 as the comparison example will be explained with reference to FIGS. 4A, 4B, 4C and 4D. The order of FIGS. 4A, 4B, 4C and 4D equals the order of time series. Each bold arrow in FIGS. 4A, 4B, 4C and 4D schematically shows a current path.

In the light emitting device 150, moisture from an outside reaches the surface 312a of the second region 312 in the n-type AlGaN layer 31 through a defect 116 of the passivation film 11 (see FIG. 4A) and a defect 926 of the second pad electrode 92 of the negative electrode 9 (see FIG. 4A). The defect 116 of the passivation film 11 is crack, pinhole or the like. The defect 926 of the second pad electrode 92 of the negative electrode 9 is crack, pinhole, grain boundary or the like.

When the surface of the second region 312 in the n-type AlGaN layer 31 contains moisture, current flows from the positive electrode 8 to the negative electrode 9 and holes (h⁺) are generated in the second region 312, and thereby the light emitting device 150 is formed with an electrical insulator (Al₂O₃) 160 by the electrochemical reaction below (FIG. 4B).

The electrochemical reaction occurs around the surface 312a of the second region 312 caused by the moisture and AlN within the second region 312 of the n-type AlGaN layer 31. Chemical reaction formula in this case is as follow:

2AlN+6h⁺→2Al³⁺+N₂

2Al³⁺+6OH⁻→Al₂O₃+3H₂O.

In short, around the surface 312a of the second region 312 in the n-type AlGaN layer 31 of the light emitting device 150, N₂ occurs and Al₂O₃ is produced by oxidation reaction, and thereby a region that becomes electrically non-conductive and expands in volume occurs.

As a result, the light emitting device 150 is liable to be subjected to moisture infiltration by the occurrence of; corrosion in the region just under the negative electrode 9 on the n-type AlGaN layer 31; damage to end part of the second pad electrode 92, damage to part of passivation film 11 on the damage part of the end part of the second pad electrode 92; and the like (FIG. 4C).

As a result, the light emitting device 150 has an area that is electrically non-conductive and expanded (electrical insulator 160 that is increased in size) because the electrochemical reaction progresses with increase in speed and the current path through the n-type AlGaN layer 31 changes. Open failure that prohibits current from flowing occurs in the light emitting device 150 because the region just under the negative electrode 9 on the n-type AlGaN layer 31 is electrically non-conductive (FIG. 4D).

In contrast, the light emitting device 100 according to the present embodiment enabled the improvement in moisture resistance in comparison with the light emitting device 150 as the comparison example. Specifically, the malfunction occurred during the energizing test under high humidity and high temperature with respect to the light emitting device 150 as the comparison example, whereas such malfunction did not occur in the light emitting device 100 according to the present embodiment even when the energizing test under high humidity and high temperature was performed.

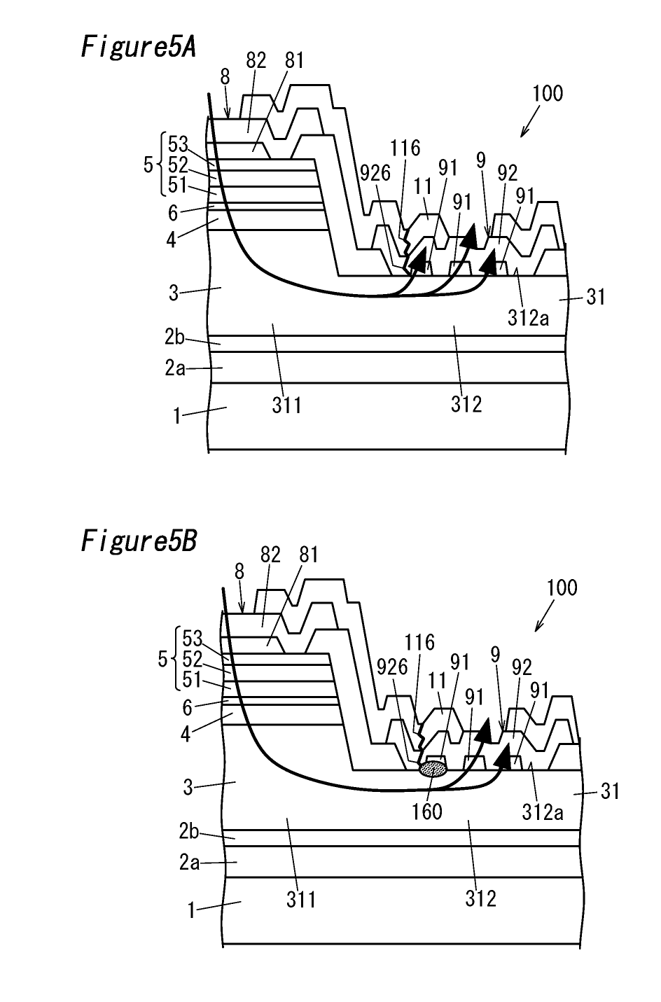

An estimation mechanism about the occurrence of such malfunction being suppressed in the light emitting device 100 will be explained with reference to FIGS. 5A and 5B. The order of FIGS. 5A and 5B equals the order of time series. Each bold arrow in FIGS. 5A and 5B schematically shows a current path.

As shown in FIG. 5A, in the light emitting device 100, the current flowing from the positive electrode 8 to the negative electrode 9 easily flows through the interfaces between the second contact electrodes 91 of the negative electrode 9 and the second region 312 of the n-type AlGaN layer 31, but hardly flows through the interfaces between the second pad electrode 92 and the second region 312 of the n-type AlGaN layer 31. In the light emitting device 100, moisture from an outside reaches the surface 312a of second region 312 in the n-type AlGaN layer 31 through the defect 116 of the passivation film 11 and the defect 926 of the second pad electrode 92.

When the surface of the second region 312 in the n-type AlGaN layer 31 contains moisture, current flows and holes (h⁺) are generated in the second region 312, and thereby the light emitting device 100 is formed with an electrical insulator 160 according to the above electrochemical reaction formula.

However, the light emitting device 100 can suppress the occurrence of the abovementioned electrochemical reaction because current flowing from the positive electrode 8 to the negative electrode 9 barely flows through the interfaces between the second pad electrode 92 and the second region 312 of the n-type AlGaN layer 31. In short, the current barely flows through each face of the second region 312 between adjoining second contact electrodes 91 of the negative electrode 9, and the light emitting device 100 can therefore suppress the occurrence of the electrochemical reaction. That results in damage by which total resistance slightly increases, and the light emitting device 100 is therefore considered to improve moisture resistance thereof.

The light emitting device 100 according to the present embodiment can also lengthen life thereof as compared with cases where metal with a high reflectivity is employed as the metal layer 92a that is the bottom layer in the second pad electrode 92 of the negative electrode 9. This is because employing Al and the like having a high reflectivity may produce current by photoelectric effect and oxidation reaction is allowed to proceed even after current interruption whereas employing Ti having reflectivity that is less than 50% may suppress the occurrence of current by photoelectric effect.

From the point of view of reduction in total resistance of the second pad electrode 92, the second metal layer 92b is preferably an Al layer. The third metal layer 92c preferably has a function as a barrier metal layer between the second metal layer 92b of the Al layer and the fourth metal layer 92d of an Au layer. Material of the third metal layer 92c is preferably one kind selected from the group consisting of Ti, Ta and Ni. It is accordingly possible to improve adhesion of the second metal layer 92b and the fourth metal layer 92d with respect to the third metal layer 92c.

As stated above, the nitride semiconductor light emitting device 100 according to the present embodiment includes the n-type nitride semiconductor layer 3, the luminous layer 4, the p-type nitride semiconductor layer 5, the substrate 1, the positive electrode 8, the negative electrode 9, the electrical insulation film 10 and the passivation film 11. The n-type nitride semiconductor layer 3 has at least the n-type AlGaN layer 31. The luminous layer 4 is formed on the n-type AlGaN layer 31 and configured to emit ultraviolet radiation. The p-type nitride semiconductor layer 5 is formed on the luminous layer 4. The substrate 1 supports the nitride semiconductor layer 20 including the n-type nitride semiconductor layer 3, the luminous layer 4 and the p-type nitride semiconductor layer 5. The substrate 1 is a single crystal substrate. The substrate 1 allows the ultraviolet radiation emitted from the luminous layer 4 to pass through. The positive electrode 8 is provided on the surface 5a of the p-type nitride semiconductor layer 5. The negative electrode 9 is provided on a region of the n-type nitride semiconductor layer 3, where the region is not covered with the luminous layer 4. The electrical insulation film 10 is formed with the first contact hole 101 and the second contact hole 102, where the positive electrode 8 is disposed inside the first contact hole 101 and the negative electrode 9 is disposed inside the second contact hole 102. The n-type nitride semiconductor layer 3, the luminous layer 4 and the p-type nitride semiconductor layer 5 are arranged from the side of the substrate 1 in that order. The n-type AlGaN layer 31 has the first region 311 that the luminous layer 4 overlaps and the second region 312 that the luminous layer 4 does not overlap, and is formed with the step (recess) that causes the surface 312a of the second region 312 to set further back than the surface 311a of the first region 311 toward the substrate 1. The electrical insulation film 10 covers the side faces 5c and part of the surface 5a of the p-type nitride semiconductor layer 5, the side faces 4c of the luminous layer 4, the side faces 311c of the first region 311 of the n-type AlGaN layer 31 and part of the surface 312a of the second region 312 in the n-type AlGaN layer 31. The positive electrode 8 includes the first contact electrode 81 that is disposed inside the first contact hole 101 in the electrical insulation film 10 and is in ohmic contact with the p-type nitride semiconductor layer 5, and the first pad electrode 82 that covers the first contact electrode 81. The negative electrode 9 includes second contact electrodes 91 that are disposed inside the second contact hole 102 in the electrical insulation film 10 and are each in ohmic contact with the n-type AlGaN layer 31, and the second pad electrode 92 that covers the second contact electrodes 91 and is in non-ohmic contact with the n-type AlGaN layer 31. The passivation film 11 covers at least the surface end part of the second pad electrode 92 and is formed with an opening 112 that exposes the central part of the second pad electrode 92. The second pad electrode 92 has a laminated construction of metal layers 92a, 92b, 92c and 92d. The metal layer 92a as the bottom layer, which is in non-ohmic contact with the n-type AlGaN layer 31, of the metal layers 92a, 92b, 92c and 92d is made from material by which reflectivity of the ultraviolet radiation emitted from the luminous layer 4 is less than 50%.

As explained above, the negative electrode 9 of the nitride semiconductor light emitting device 100 includes the second contact electrodes 91 that are in ohmic contact with the n-type AlGaN layer 31, and the second pad electrode 92 that is in non-ohmic contact with the n-type AlGaN layer 31. In the negative electrode 9, the metal layer 92a, which is in non-ohmic contact with the n-type AlGaN layer 31, of the metal layers 92a, 92b, 92c and 92d is made from the material by which the reflectivity of the ultraviolet radiation emitted from the luminous layer 4 is less than 50%. The nitride semiconductor light emitting device 100 can therefore improve moisture resistance thereof without changing the plan-view size of the negative electrode 9 as compared with cases where the negative electrode 9 includes the second contact electrode 91 and the second pad electrode 92 only one each like the light emitting device 150.

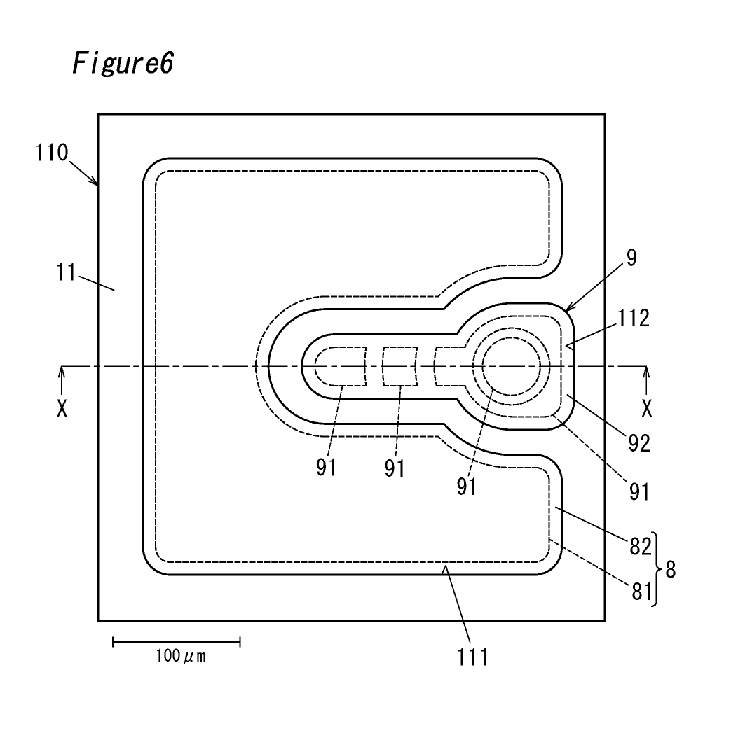

FIG. 6 is a schematic plan of a nitride semiconductor light emitting device 110 according to Modified Example 1 of Embodiment 1. The nitride semiconductor light emitting device 110 has basic construction that is the same as that of the nitride semiconductor light emitting device 100, and differs therefrom only in that second contact electrodes 91 of a negative electrode 9 have different shapes. In the nitride semiconductor light emitting device 110, like kind components are assigned the same reference numerals as depicted in the light emitting device 100, and are not described herein.

The negative electrode 9 of the nitride semiconductor light emitting device 110 has four second contact electrodes 91, one of which is circular in shape, and another of which is annular in shape and surrounds the circular second contact electrode 91. The circular second contact electrode 91 is preferably 45 μm or more in diameter.

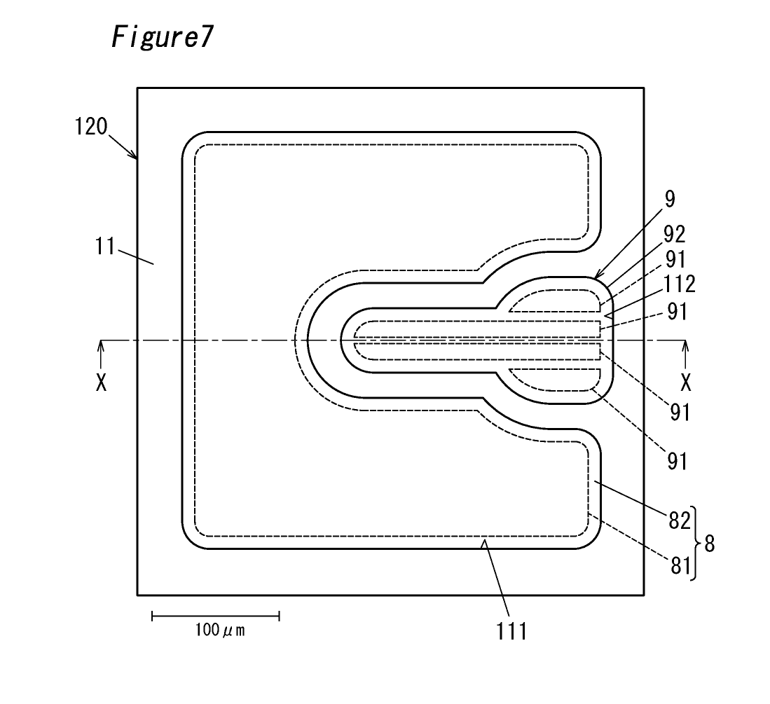

FIG. 7 is a schematic plan of a nitride semiconductor light emitting device 120 according to Modified Example 2 of Embodiment 1. The nitride semiconductor light emitting device 120 has basic construction that is the same as that of the nitride semiconductor light emitting device 100, and differs therefrom only in that second contact electrodes 91 of a negative electrode 9 have different shapes. In the nitride semiconductor light emitting device 120, like kind components are assigned the same reference numerals as depicted in the light emitting device 100, and are not described herein.

The negative electrode 9 of the nitride semiconductor light emitting device 120 has second contact electrodes 91 that are linear in shape and arranged in parallel with each other. In short, the second contact electrodes 91 have a stripe pattern.

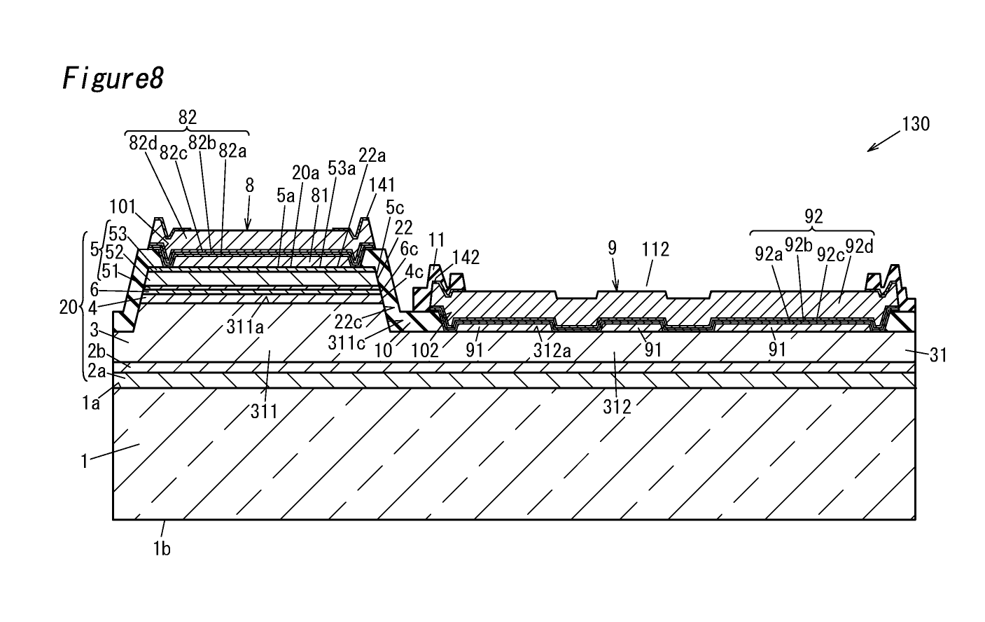

FIG. 8 is a schematic sectional view of a nitride semiconductor light emitting device 130 according to Modified Example 3 of Embodiment 1. The nitride semiconductor light emitting device 130 has basic construction that is the same as that of the nitride semiconductor light emitting device 100, and differs therefrom only in that a passivation film 11 has a different pattern. In the nitride semiconductor light emitting device 130, like kind components are assigned the same reference numerals as depicted in the light emitting device 100, and are not described herein.

The passivation film 11 of the nitride semiconductor light emitting device 130 is formed to cover surface end part of a second pad electrode 92 of a negative electrode 9, side faces of the second pad electrode 92, and part of a surface of an electrical insulation film 10 around the second pad electrode 92. The passivation film 11 is also formed with an opening 112 that exposes central part of the second pad electrode 92.

The nitride semiconductor light emitting device 130 can improve moisture resistance thereof without changing a plan-view size of the negative electrode 9 as compared with cases where the negative electrode 9 includes the second contact electrode 91 and the second pad electrode 92 only one each like the light emitting device 150 as the comparison example (see FIG. 4A).

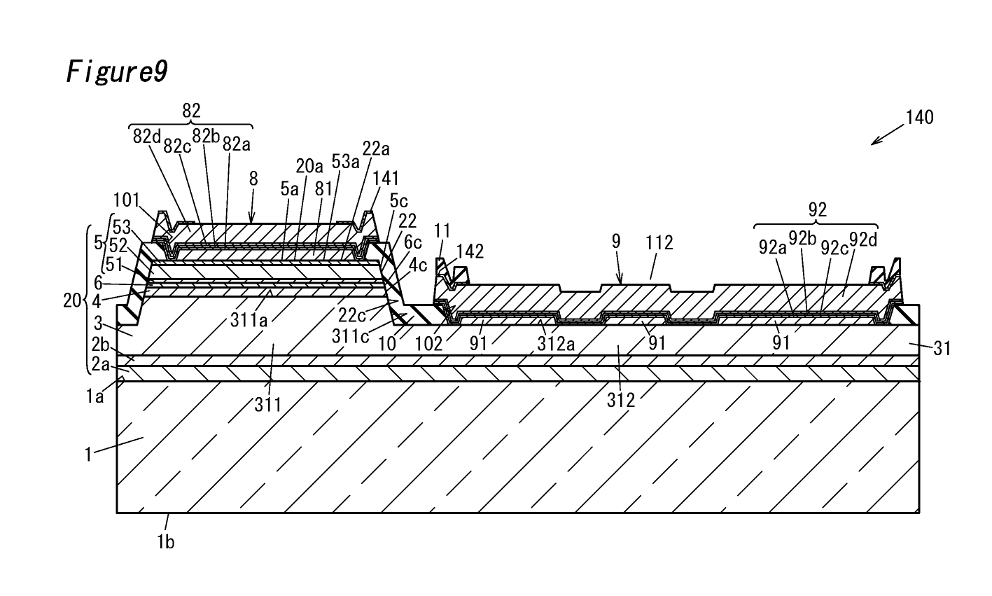

FIG. 9 is a schematic sectional view of a nitride semiconductor light emitting device 140 according to Modified Example 4 of Embodiment 1. The nitride semiconductor light emitting device 140 has basic construction that is the same as that of the nitride semiconductor light emitting device 100, and differs therefrom only in that a passivation film 11 has a different pattern. In the nitride semiconductor light emitting device 140, like kind components are assigned the same reference numerals as depicted in the light emitting device 100, and are not described herein.

The passivation film 11 of the nitride semiconductor light emitting device 140 is formed to cover only surface end part of a second pad electrode 92 of a negative electrode 9, and formed with an opening 112 that exposes central part of the second pad electrode 92.

The nitride semiconductor light emitting device 140 can improve moisture resistance thereof without changing the plan-view size of the negative electrode 9 as compared with cases where the negative electrode 9 includes the second contact electrode 91 and the second pad electrode 92 only one each like the light emitting device 150 as the comparison example (see FIG. 4A).

### Embodiment 2

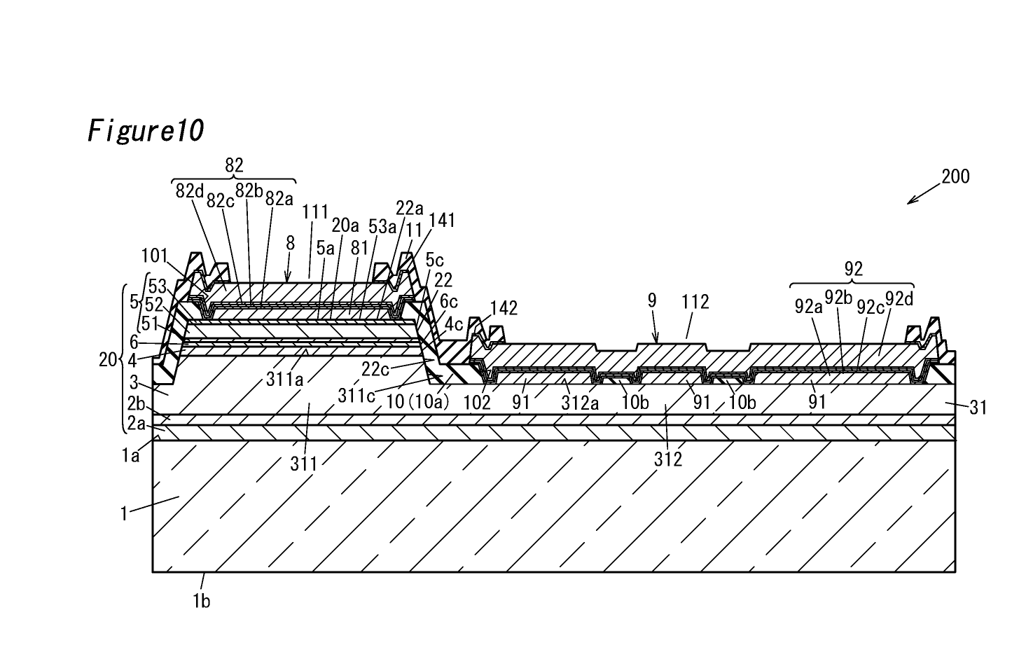

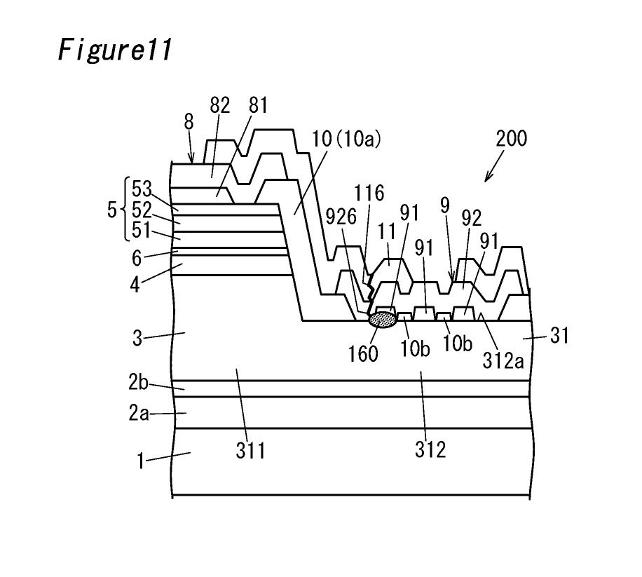

Hereinafter, a nitride semiconductor light emitting device 200 according to the present embodiment will be explained with reference to FIGS. 10 and 11. In the nitride semiconductor light emitting device 200, like kind components are assigned the same reference numerals as depicted in the light emitting device 100, and are not described herein.

The nitride semiconductor light emitting device 200 has basic construction that is almost the same as that of the light emitting device 100, and differs therefrom in that it further includes a second electrical insulation film 10b that is different from an electrical insulation film 10 as a first electrical insulation film 10a. The second electrical insulation film 10b is formed on a surface 312a of a second region 312 in an n-type AlGaN layer 31 between each adjoining second contact electrodes 91 of second contact electrodes 91. The nitride semiconductor light emitting device 200 can suppress sideways spreading of an electrical insulator 160 by the second electrical insulation film 10b even if the electrical insulator 160 is formed in the second region 312 of the n-type AlGaN layer 31 as shown in FIG. 11. The nitride semiconductor light emitting device 200 can therefore further improve moisture resistance thereof as compared with the light emitting device 100 according to Embodiment 1.

The second electrical insulation film 10b is preferably a silicon oxide film. The second electrical insulation film 10b can accordingly be formed by the same process as the first electrical insulation film 10a. When the second electrical insulation film 10b has the same thickness as the first electrical insulation film 10a, it can be formed at the same time with the first electrical insulation film 10a.

### Embodiment 3

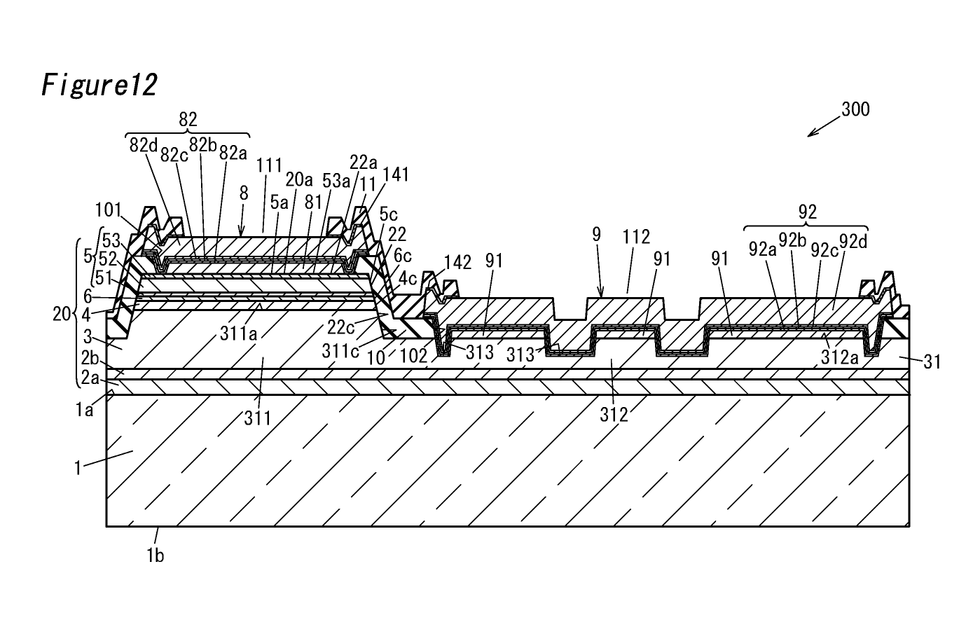

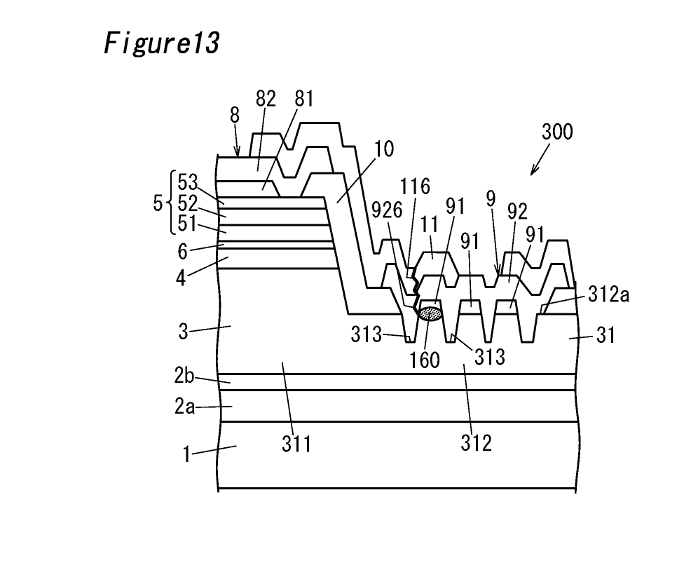

Hereinafter, a nitride semiconductor light emitting device 300 according to the present embodiment will be explained with reference to FIGS. 12 and 13. In the nitride semiconductor light emitting device 300, like kind components are assigned the same reference numerals as depicted in the light emitting device 100, and are not described herein.

The nitride semiconductor light emitting device 300 has basic construction that is almost the same as that of the light emitting device 100. The nitride semiconductor light emitting device 300 differs from the light emitting device 100 in that it is formed with depressions 313 in a surface 312a of a second region 312 in an n-type AlGaN layer 31, between each adjoining second contact electrodes of second contact electrodes and at the outside thereof. The nitride semiconductor light emitting device 300 can suppress sideways spreading of an electrical insulator 160 by the depressions 313 even if the electrical insulator 160 is formed in the second region 312 of the n-type AlGaN layer 31 as shown in FIG. 13. The nitride semiconductor light emitting device 300 can therefore further improve moisture resistance thereof as compared with the light emitting device 100 according to Embodiment 1.

Respective material, numerical values and the like described in Embodiments 1 to 3 just show preferable examples, and are not intended to be limited thereto. Appropriate modifications may be made in the configuration of the invention of the present application without departing from the scope of the invention.

For example, each part of the configurations of Modified Example 1, Modified Example 2, Modified Example 3 and Modified Example 4 in Embodiment 1 may be applied to Embodiment 2 or 3.

The single crystal substrate is not limited to a sapphire substrate, but may be, for example a group III nitride semiconductor crystal substrate. For example, an AlN substrate may be employed as the group III nitride semiconductor crystal substrate.

### REFERENCE SIGNS LIST

1 Substrate
3 N-type nitride semiconductor layer
31 N-type AlGaN layer
311 First region
312 Second region
312a Surface
313 Depression
4 Luminous layer
5 P-type nitride semiconductor layer
8 Positive electrode
81 First contact electrode
82 First pad electrode
9 Negative electrode
91 Second contact electrodes
92 Second pad electrode
92a Metal layer
92b Metal layer
92c Metal layer
92d Metal layer
10 Electrical insulation film
10a First electrical insulation film
10b Second electrical insulation film
101 First contact hole
102 Second contact hole
11 Passivation film
112 Opening (Second opening)
100, 110, 120, 130, 140, 200, 300 Nitride semiconductor light emitting device

1. A nitride semiconductor light emitting device, comprising
an n-type nitride semiconductor layer that has at least an n-type AlGaN layer,
a luminous layer that is formed on the n-type AlGaN layer and configured to emit ultraviolet radiation,
a p-type nitride semiconductor layer that is formed on the luminous layer,
a substrate that is a single crystal substrate that supports a nitride semiconductor layer including the n-type nitride semiconductor layer, the luminous layer and the p-type nitride semiconductor layer and allows the ultraviolet radiation emitted from the luminous layer to pass through,
a positive electrode that is provided on a surface of the p-type nitride semiconductor layer,
a negative electrode that is provided on a region of the n-type nitride semiconductor layer, the region being not covered with the luminous layer,
an electrical insulation film in which a first contact hole and a second contact hole are formed, the positive electrode being disposed inside the first contact hole, the negative electrode being disposed inside the second contact hole, and
a passivation film, wherein
the n-type nitride semiconductor layer, the luminous layer and the p-type nitride semiconductor layer are arranged from a side of the substrate in that order,
the n-type AlGaN layer has a first region that the luminous layer overlaps and a second region that the luminous layer does not overlap, and is formed with a step that causes a surface of the second region to set further back than a surface of the first region toward the substrate,
the electrical insulation film covers side faces and part of the surface of the p-type nitride semiconductor layer, side faces of the luminous layer, side faces of the first region of the n-type AlGaN layer and part of the surface of the second region of the n-type AlGaN layer,
the positive electrode includes a first contact electrode that is disposed inside the first contact hole in the electrical insulation film and is in ohmic contact with the p-type nitride semiconductor layer, and a first pad electrode that covers the first contact electrode,
the negative electrode includes second contact electrodes that are disposed inside the second contact hole in the electrical insulation film and are each in ohmic contact with the n-type AlGaN layer, and a second pad electrode that covers the second contact electrodes and is in non-ohmic contact with the n-type AlGaN layer,
the passivation film covers at least surface end part of the second pad electrode and is formed with an opening that exposes central part of the second pad electrode,
the second pad electrode has a laminated construction of metal layers, and
a metal layer as a bottom layer, which is in non-ohmic contact with the n-type AlGaN layer, of the metal layers is made from material by which reflectivity of the ultraviolet radiation emitted from the luminous layer is less than 50%.

2. The nitride semiconductor light emitting device of claim 1, wherein the material of the metal layer as the bottom layer is one kind selected from a group consisting of Ti, Mo, Cr and W.

3. The nitride semiconductor light emitting device of claim 1, further comprising a second electrical insulation film that is different from the electrical insulation film as a first electrical insulation film, wherein
the second electrical insulation film is formed on the surface of the second region in the n-type AlGaN layer between adjoining second contact electrodes of the second contact electrodes.

4. The nitride semiconductor light emitting device of claim 1, wherein the nitride semiconductor light emitting device is formed with a depression in the surface of the second region in the n-type AlGaN layer between adjoining second contact electrodes of the second contact electrodes.

5. The nitride semiconductor light emitting device of claim 1, wherein at least one second contact electrode of the second contact electrodes is greater than a circle with a diameter of 45 μm as seen from a thickness direction of the substrate.

6. The nitride semiconductor light emitting device of claim 2, further comprising a second electrical insulation film that is different from the electrical insulation film as a first electrical insulation film, wherein
the second electrical insulation film is formed on the surface of the second region in the n-type AlGaN layer between adjoining second contact electrodes of the second contact electrodes.

7. The nitride semiconductor light emitting device of claim 2, wherein the nitride semiconductor light emitting device is formed with a depression in the surface of the second region in the n-type AlGaN layer between adjoining second contact electrodes of the second contact electrodes.

8. The nitride semiconductor light emitting device of claim 3, wherein the nitride semiconductor light emitting device is formed with a depression in the surface of the second region in the n-type AlGaN layer between adjoining second contact electrodes of the second contact electrodes.

9. The nitride semiconductor light emitting device of claim 2, wherein at least one second contact electrode of the second contact electrodes is greater than a circle with a diameter of 45 μm as seen from a thickness direction of the substrate.

10. The nitride semiconductor light emitting device of claim 3, wherein at least one second contact electrode of the second contact electrodes is greater than a circle with a diameter of 45 μm as seen from a thickness direction of the substrate.

11. The nitride semiconductor light emitting device of claim 4, wherein at least one second contact electrode of the second contact electrodes is greater than a circle with a diameter of 45 μm as seen from a thickness direction of the substrate.
